(19) United States
(12) Patent Application Publication
(10) Pub. No.: US 2026/0026384 A1
(43) Pub. Date: Jan. 22, 2026

(54) SUBSTRATE BONDING DEVICE AND METHOD OF BONDING SUBSTRATES

(71) Applicant: Samsung Electronics Co., Ltd., Suwon-si (KR)

(72) Inventors: Jaeho HONG, Suwon-si (KR); Taehong MIN, Suwon-si (KR); Sangjun PARK, Suwon-si (KR); Tae-Hoi PARK, Suwon-si (KR); Sang-Ho YUN, Suwon-si (KR)

(21) Appl. No.: 19/006,695

(22) Filed: Dec. 31, 2024

(30) Foreign Application Priority Data
Jul. 17, 2024 (KR) 10-2024-0094574

(51) Int. Cl. H01L 23/00

(52) U.S. Cl. CPC H01L 24/74; H01L 24/80; H01L 24/94; H01L 2224/74; H01L 2224/80201; H01L 2224/94

(57) ABSTRACT

Provided is a substrate bonding device in which a risk of substrate damage due to vibration is alleviated, the substrate bonding device including a first chuck configured to support a lower substrate, a second chuck configured to grip an upper substrate facing the lower substrate in a first direction perpendicular to an upper surface of the lower substrate, and a press disposed at a center of the second chuck and configured to push the upper substrate toward the lower substrate in the first direction, and the press includes a first pressurizing part and a second pressurizing part which are spaced apart from each other in the first direction.

### CROSS-REFERENCE TO RELATED APPLICATION(S)

This application claims priority under 35 U.S.C. § 119 to and benefit of Korean Patent Application No. 10-2024-0094574, filed on Jul. 17, 2024, in the Korean Intellectual Property Office, the disclosure of which is incorporated herein by reference.

### BACKGROUND

### 1. Field of the Invention

Example embodiments relate to a substrate bonding device and a method of bonding substrates.

### 2. Description of the Related Art

In a fabrication process of a semiconductor device, a substrate bonding process may be conducted for bonding two or more substrates together. The substrate bonding process may be performed to increase a packaging density of semiconductor chips in a semiconductor device. For example, a semiconductor module with a structure of stacked semiconductor chips may reduce wiring lengths between semiconductor chips, improve signal processing speed, perform high-speed signal processing, and increase a packaging density of semiconductor chips. When fabricating the semiconductor module with the stacked semiconductor chip structure, a process of bonding wafers and then cutting into units of stacked semiconductor chips may enhance productivity compared to bonding units of semiconductor chips.

The substrate bonding process may be performed in a wafer-to-wafer manner of directly bonding two wafers without a separate medium. Generally, the wafer-to-wafer manner may be performed using a bonding device including a bonding chuck supporting a wafer and a component pressurizing/pressing a wafer.

### SUMMARY

An aspect of the present disclosure provides a substrate bonding device and a method of bonding substrates, in which a risk of substrate damage due to vibration is alleviated.

Another aspect of the disclosure provides a substrate bonding device and a method of bonding substrates, in which a substrate bonding process yield is enhanced.

The inventive concept is not limited to the technical features described above, and other unstated technical features may be made apparent to those skilled in the art from the following description.

According to an aspect, there is provided a substrate bonding device including a first chuck configured to support a lower substrate, a second chuck configured to grip an upper substrate facing the lower substrate in a first direction perpendicular to an upper surface of the lower substrate, and a press disposed at a center of the second chuck and configured to push the upper substrate toward the lower substrate in the first direction, and the press may include a first pressurizing part and a second pressurizing part which are spaced apart from each other in the first direction.

According to another aspect, there is also provided a substrate bonding device including a first chuck configured to support a lower substrate, a second chuck configured to support an upper substrate facing the lower substrate in a first direction perpendicular to an upper surface of the lower substrate, and a press disposed in a hole penetrating through a center of the second chuck and configured to push the upper substrate toward the lower substrate in the first direction, and the press may include a first pressurizing part and a second pressurizing part which are spaced apart from each other in the first direction, and the first pressurizing part may be configured to contact an upper surface of the second pressurizing part when moved along the first direction, and the second pressurizing part may be configured to contact the upper substrate when moved along the first direction.

According to another aspect, there is also provided a method of bonding substrates, the method including providing a substrate bonding device including a first chuck, a second chuck facing the first chuck in a first direction perpendicular to an upper surface of the first chuck, and a press disposed in a hole penetrating through a center of the second chuck and including a first pressurizing part and a second pressurizing part which are aligned in the first direction, disposing a lower substrate on the first chuck, disposing an upper substrate on the second chuck, striking the second pressurizing part by moving the first pressurizing part in the first direction, striking a center portion of the upper substrate by moving the second pressurizing part in the first direction, and bonding the center portion of the upper substrate to the lower substrate by separating the center portion of the upper substrate from the second chuck.

Additional aspects of example embodiments will be set forth in part in the description which follows and, in part, will be apparent from the description, or may be learned by practice of the disclosure.

According to example embodiments of the present disclosure, it is possible to alleviate a risk of substrate damage due to vibration when bonding substrates.

According to example embodiments of the present disclosure, it is possible to enhance a substrate bonding process yield.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view for illustrating a substrate bonding device according to some example embodiments;

FIG. 2 is an example cross-sectional view taken along line I-I of FIG. 1 for illustrating a substrate bonding device according to some example embodiments;

FIG. 3 is an example enlarged view showing part P of FIG. 2;

FIGS. 4 to 8 are example enlarged views showing part P of FIG. 2 according to some other example embodiments;

FIG. 9 is a cross-sectional view for illustrating a substrate bonding device according to still other example embodiments; and

FIGS. 10 to 13 are diagrams for illustrating a method of bonding substrates according to some example embodiments.

### DETAILED DESCRIPTION

Before describing example embodiments in detail, it should be noted that the words and terminologies used in the specification and claims are not to be construed as limited to common or dictionary meanings but construed as meanings and conceptions coinciding with the technical spirit of the present disclosure under a principle that the inventor(s) may appropriately define the conception of the terminologies to explain the invention in the optimum manner. Therefore, the example embodiments described in the specification and the configurations illustrated in the drawings are no more than the most preferred example embodiments of the present disclosure and do not fully cover the spirit of the present disclosure. Accordingly, it should be understood that there may be various equivalents and modifications that may replace those when this application is filed.

In the descriptions below, a singular expression may include/represent a plural expression unless apparently indicates otherwise. It should be understood that terms such as “comprise” or “include” are intended to indicate the presence of a feature, a number, a step, an operation, an element, a component, or a combination thereof which are described in the specification and not intended to exclude the possibility of the presence or addition of one or more other features, numbers, steps, operations, elements, components, or combinations thereof.

In addition, expressions such as upper side, upper portion, lower side, lower portion, side surface, front surface, and rear surface hereinafter are represented based on a direction illustrated in a drawing and may be represented otherwise when the direction of a corresponding object changes. The shape or size of elements in drawings may be exaggerated for clearer description.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Hereinafter, example embodiments of the present disclosure will be described with reference to the accompanying drawings.

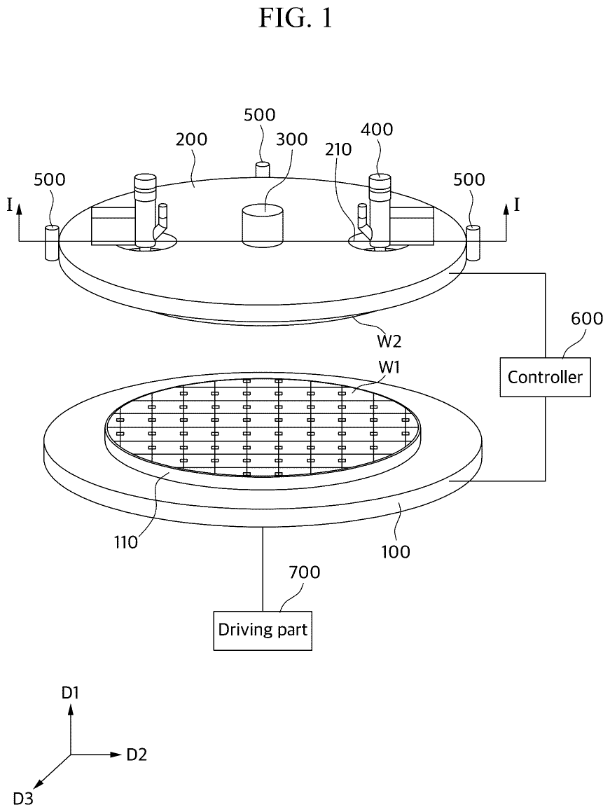

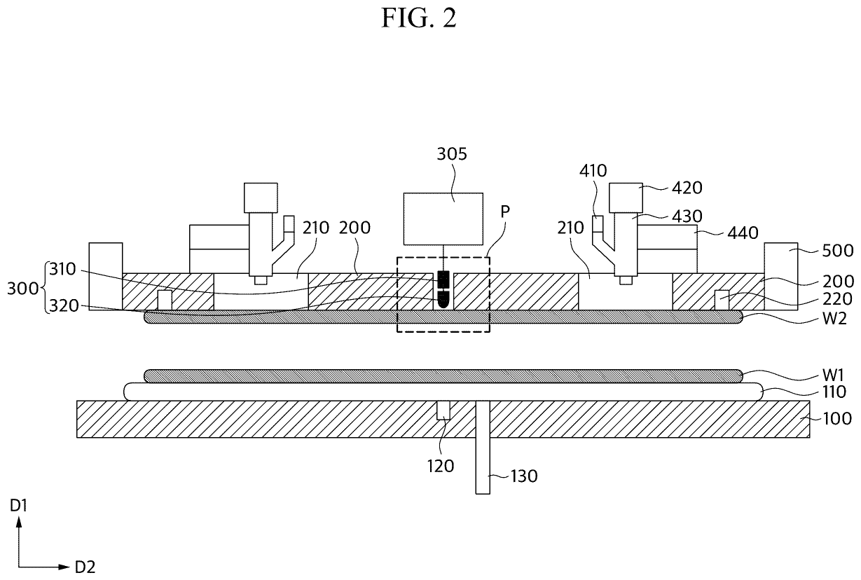

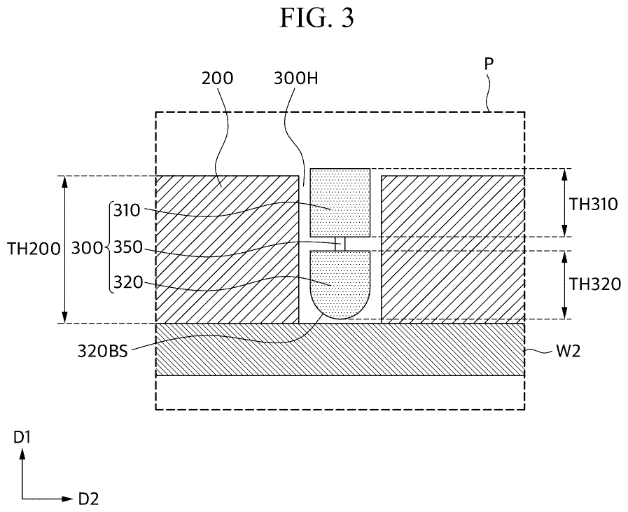

FIG. 1 is a perspective view for illustrating a substrate bonding device according to some example embodiments. FIG. 2 is an example cross-sectional view taken along line I-I of FIG. 1 for illustrating a substrate bonding device according to some example embodiments. FIG. 3 is an example enlarged view showing part P of FIG. 2.

Referring to FIGS. 1 to 3, the substrate bonding device according to some example embodiments may include a first chuck 100, a second chuck 200, a bonding initiation part 300, a photographing part 400, a distance sensor 500, a controller 600, and a driving part (e.g., a drive) 700.

According to some example embodiments, the first chuck 100 may support a lower substrate W1. For example, the first chuck 100 may be in contact with a bottom surface of the lower substrate W1 and support the lower substrate W1. For example, the bottom surface of the lower substrate W1 may be a nonactive surface.

According to some example embodiments, the first chuck 100 may face the second chuck 200 in a first direction D1. The first direction D1 may be a direction perpendicular to an upper surface of the first chuck 100. For example, the first direction D1 may be a direction perpendicular to an upper surface and/or the bottom surface of the lower substrate W1 and/or an upper surface and/or a bottom surface of an upper substrate W2. The first chuck 100 may have a surface defined by a second direction D2 and a third direction D3. The second direction D2 and the third direction D3 may be directions perpendicular to the first direction D1 and parallel to a surface of the lower substrate W1 and/or the upper substrate W2.

According to some example embodiments, a support plate 110 may be disposed on the first chuck 100. The support plate 110 may be disposed between the lower substrate W1 and the first chuck 100. The support plate 110 may support the lower substrate W1. The support plate 110 may be fixed by the first chuck 100.

For example, the support plate 110 may adhere to the first chuck 100 through vacuum pressure supplied through a lower vacuum hole 120 disposed in the first chuck 100. Though not illustrated in FIGS. 1 and 2, the lower vacuum hole 120 may be connected to a gas pipe, a vacuum pump, and/or the like which may form vacuum pressure.

According to some example embodiments, the support plate 110 may support the lower substrate W1 using electrostatic force. For example, the support plate 110 may include an electrode to which electric power is applied from outside such that the electrode generates electrostatic force. The support plate 110 may support the lower substrate W1 using the electrostatic force generated from the electrode in the support plate 110. The support plate 110 may include metal, ceramic, rubber, or a combination thereof. For example, the support plate 110 may include aluminum or silicon carbide (SiC).

According to some example embodiments, the support plate 110 may be disposed to be movable by the driving part 700 and a vertical supporter 130 and may adjust a distance between the lower substrate W1 and the upper substrate W2. The support plate 110 may be moved up and down in the first direction D1 by the vertical supporter 130.

According to some example embodiments, the support plate 110 may be connected to and/or contact the vertical supporter 130. The vertical supporter 130 may penetrate through the first chuck 100 in the first direction D1 and be connected to and/or contact the support plate 110. The vertical supporter 130 may move the support plate 110 in the first direction D1. The vertical supporter 130 may transform a shape of the support plate 110 in the first direction D1. For example, the vertical supporter 130 may lift a center portion of the support plate 110 in the first direction D1 so that a center portion of the lower substrate W1 disposed on the support plate 110 is closer to the upper substrate W2. For example, when the vertical supporter 130 push the center portion of the support plate upwards, a level of a center portion of an upper surface of the lower substrate W1 positioned on the support plate 110 may be higher than a level of an edge portion of the upper surface of the lower substrate W1.

According to some example embodiments, the vertical supporter 130 may penetrate through a center portion of the first chuck 100. Accordingly, when the vertical supporter 130 lifts in the first direction D1 to move the support plate 110 in the first direction D1, the center portion of the support plate 110 may be transformed to be convex toward the second chuck 200, and an edge portion thereof may not be transformed and fixed on the first chuck 100.

According to some example embodiments, the second chuck 200 may support the upper substrate W2. For example, the second chuck 200 may be in contact with the upper surface of the upper substrate W2 and support the upper substrate W2. For example, the bottom surface of the upper substrate W2 may be an active surface of the upper substrate W2, and the upper surface of the upper substrate W2 may be a nonactive surface of the upper substrate W2.

According to some example embodiments, the second chuck 200 may face the first chuck 100 in the first direction D1. The second chuck 200 may have a surface defined by the second direction D2 and the third direction D3. For example, the surface of the second chuck 200 may be parallel to the second direction D2 and the third direction D3. The first chuck 100 and the second chuck 200 may be spaced apart in the first direction with the lower substrate W1 and the upper substrate W2 in between.

According to some example embodiments, the second chuck 200 may support the upper substrate W2 using electrostatic force. For example, the second chuck 200 may include an electrode to which electric power is applied from outside such that the electrode generates electrostatic force. The second chuck 200 may support the upper substrate W2 using the electrostatic force generated from the electrode in the second chuck 200. For another example, the second chuck 200 may fix the upper surface of the upper substrate W2 on a bottom surface of the second chuck 200 using vacuum pressure.

For example, the upper substrate W2 may adhere to the second chuck 200 through vacuum pressure supplied through an upper vacuum hole 220 disposed in the second chuck 200. The upper vacuum hole 220 may be disposed at an outer portion of the second chuck 200 compared to the bonding initiation part 300, e.g., in a plan view. The upper vacuum hole 220 may grip the upper substrate W2 through vacuum pressure. Though not illustrated in FIGS. 1 and 2, the upper vacuum hole 220 may be connected to a gas pipe, a vacuum pump, and/or the like which may form vacuum pressure. For example, two or more upper vacuum holes 220 may be formed at edge portions of the second chuck 200, along a circumference of the second chuck 200.

According to some example embodiments, an observation window 210 penetrating through the second chuck 200 in the first direction D1 may be formed in the second chuck 200. The observation window 210 may be a region through which the photographing part 400 photographs an image of the lower substrate W1 and the upper substrate W2. The observation window 210 may be formed as a hole penetrating through the second chuck 200. The upper surface of the upper substrate W2 may be exposed through the observation window 210. The shape of the observation window 210 may be variously changed depending on example embodiments. For example, the observation window 210 may be circular, square, rectangular, hexagonal, etc. in a plan view. For example, the observation window 210 may further include a cover with a light-transmissive material.

According to some example embodiments, the bonding initiation part 300 may penetrate through the second chuck 200. For example, a through hole 300H may be formed to penetrate through the second chuck 200, and the bonding initiation part 300 may be disposed within the through hole 300H. A width or diameter of the bonding initiation part 300, e.g., in a horizontal direction, may be less than a width or diameter of the through hole 300H, e.g., in the horizontal direction. The bonding initiation part 300 may penetrate through a center portion of the second chuck 200. The bonding initiation part 300 may strike/push the upper substrate W2. The bonding initiation part 300 may pressurize/push/press the upper substrate W2 toward the lower substrate W1. For example, the bonding initiation part 300 may pressurize/push/press the upper substrate W2 downwards in the first direction D1 so that the upper substrate W2 is closer to the lower substrate W1. The bonding initiation part 300 may apply pressure to the upper surface of the upper substrate W2. For example, the bonding initiation part 300 may apply pressure to a center of the upper surface of the upper substrate W2. For example, the bonding initiation part 300 may be a press pushing down a center portion (e.g., the center) of the upper surface of the upper substrate W2.

According to some example embodiments, the bonding initiation part 300 may include a first pressurizing part 310 and a second pressurizing part 320. The first pressurizing part 310 and the second pressurizing part 320 may be disposed within the through hole 300H. A width/diameter of the first pressurizing part 310 and a width/diameter of the second pressurizing part 320, e.g., in a horizontal direction, may be less than the width/diameter of the through hole 300H, e.g., in the horizontal direction. The first pressurizing part 310 and the second pressurizing part 320 may be disposed to be spaced apart from each other in the first direction D1. The first pressurizing part 310 and the second pressurizing part 320 may include an elastic material. For example, the first pressurizing part 310 and the second pressurizing part 320 may include silicon or rubber. The first pressurizing part 310 and the second pressurizing part 320 including the elastic material may mitigate vibration and/or impact generated due to pressurization.

According to some example embodiments, the bonding initiation part 300 may be connected to an actuator 305. The actuator 305 may cause the first pressurizing part 310 to move as reciprocating in the first direction D1. For example, the actuator 305 may cause the first pressurizing part 310 to move in the first direction D1 and strike/push the second pressurizing part 320. For example, the actuator 305 may provide a force/power to move the first pressuring part 310. For example, the actuator 305 may be a driver moving/controlling the first pressurizing part 310 and/or the second pressuring part 320.

According to some example embodiments, the first pressurizing part 310 may be disposed on the second pressurizing part 320. The first pressurizing part 310 may be disposed to be spaced more apart from the upper substrate W2 than the second pressurizing part 320. The first pressurizing part 310 may move in the first direction D1 on the second pressurizing part 320. For example, the first pressurizing part 310 may move in the first direction D1 and pressurize the second pressurizing part 320. For example, the first pressuring part 310 may push the second pressuring part 320 downwards.

According to some example embodiments, the second pressurizing part 320 may be disposed below the first pressurizing part 310. The second pressurizing part 320 may be disposed to be more adjacent (closer) to the upper substrate W2 than the first pressurizing part 310. A bottom surface 320BS of the second pressurizing part may be formed as a curved surface convex toward the upper substrate W2. The bottom surface 320BS of the second pressurizing part may be curved convexly toward the upper substrate W2. The second pressurizing part 320 may move between the first pressurizing part 310 and the upper substrate W2 in the first direction D1. The second pressurizing part 320 may move toward the upper substrate W2 by the first pressurizing part 310. The second pressurizing part 320 may pressurize (e.g., push down) the upper substrate W2. The second pressurizing part 320 may strike the upper substrate W2.

According to some example embodiments, the first pressurizing part 310 and the second pressurizing part 320 may be connected through a connection part 350. The connection part 350 may be disposed between the first pressurizing part 310 and the second pressurizing part 320. The connection part 350 may include or be formed of an elastic material. For example, the connection part 350 may include or be formed of silicon or rubber. For example, the connection part 350 may be an elastic connector connecting the first pressurizing part 310 and the second pressurizing part 320 to each other and interposed therebetween. For example, while the connection part 350 absorbs some vibration/impact applied to the first pressurizing part 310, the connection part 350 is configured to transfer enough amount of power transferred from the first pressurizing part 310 to the second pressurizing part 320 such that the second pressurizing part 320 pushes the upper substrate W2 when a predetermined force is applied to the first pressurizing part 310.

According to some example embodiments, as the first pressurizing part 310 strikes the second pressurizing part 320 and, accordingly, the second pressurizing part 320 strikes the upper substrate W2, a magnitude of vibration or impact transmitted to the upper substrate W2 by the bonding initiation part 300 may decrease. For example, as a magnitude of vibration generated while the first pressurizing part 310 is moved in the first direction D1 by the actuator 305 is transmitted indirectly to the upper substrate W2 through the second pressurizing part 320, a magnitude of vibration and/or impact may decrease. For example, after the second pressurizing part 320 partially absorbs vibration or impact generated due to a strike of the first pressurizing part 310, the second pressurizing part 320 may strike the upper substrate W2. Therefore, a risk of damage to the upper substrate W2 due to vibration or impact by a strike of the bonding initiation part 300 may be alleviated. Accordingly, bonding the lower substrate W1 and the upper substrate W2 may be performed stably due to a reduction in vibration or impact, which may enhance a substrate bonding process yield.

According to some example embodiments, a thickness TH310 of the first pressurizing part and a thickness TH320 of the second pressurizing part may be identical. In addition, a sum of the thickness TH310 of the first pressurizing part and the thickness TH320 of the second pressurizing part may be identical to a thickness TH200 of the second chuck or less than the thickness TH200 of the second chuck. For example, the thickness TH310 of the first pressurizing part may be a distance between an upper surface and a bottom surface of the first pressurizing part 310. The thickness TH320 of the second pressurizing part may be a distance between an upper surface and a lowermost point of the bottom surface of the second pressurizing part 320. The thickness TH200 of the second chuck may be a distance between an upper surface and the bottom surface of the second chuck 200 in the first direction D1.

According to some example embodiments, the photographing part 400 may be disposed on the second chuck 200. The photographing part 400 may be configured to generate an image for identifying whether the lower substrate W1 and the upper substrate W2 are aligned. The photographing part 400 may photograph the lower substrate W1 and the upper substrate W2 a plurality of times and transmit the generated images to the controller 600.

According to some example embodiments, the photographing part 400 may include a light source 410, a camera 420, a body part 430, and a moving stage 440. The light source 410 may emit light (transmission light). The body part 430 may provide a path of light traveling. For example, the body part 430 may include a barrel.

According to some example embodiments, the transmission light emitted from the light source 410 may travel along the body part 430 and be emitted to the outside of the photographing part 400 at a bottom end of the body part 430. The emitted light from the bottom end of the body part 430 may radiate toward the upper substrate W2 disposed on the second chuck 200. A portion of the transmission light radiating toward the upper substrate W2 may penetrate through the upper substrate W2 and radiate to the lower substrate W1. Measurement light reflected by the lower substrate W1 may penetrate the upper substrate W2 and be collected in the photographing part 400. The body part 430 may be divided into a passing path of the transmission light emitted from the light source 410 and a path of the measurement light reflected by the lower substrate W1 and the upper substrate W2 and inputted to the camera 420. For example, an object lens may be disposed at the bottom end of the body part 430.

According to some example embodiments, the camera 420 may be configured to photograph an image of the lower substrate W1 and the upper substrate W2. The camera 420 may receive the measurement light reflected by surfaces of the lower substrate W1 and the upper substrate W2. For example, the camera 420 may include or may be an infrared camera. However, the inventive concept is not limited thereto.

According to some example embodiments, the moving stage 440 may be disposed on the second chuck 200. The moving stage 440 may be fixed on the second chuck 200 and move the body part 430 in the second direction D2 and/or the third direction D3.

According to some example embodiments, the distance sensor 500 may be disposed at an outer circumference of the second chuck 200. The distance sensor 500 may sense a distance between the first chuck 100 and the second chuck 200 in the first direction D1. For example, the distance sensor 500 may measure the distance between the first chuck 100 and the second chuck 200 in the first direction D1 by radiating an electromagnetic wave to the first chuck 100 and then analyzing an electromagnetic wave reflected thereby. A plurality of distance sensors 500 may be disposed along a circumference of the second chuck 200. Through the plurality of distance sensors 500, it may be measured whether the first chuck 100 and the second chuck 200 are parallel with each other. In addition, by subtracting thicknesses of the lower substrate W1 and the upper substrate W2 which are previously measured from the distance between the first chuck 100 and the second chuck 200 in the first direction D1, a distance between the lower substrate W1 and the upper substrate W2 in the first direction D1 may be measured.

According to some example embodiments, the controller 600 may control the first chuck 100, the second chuck 200, the bonding initiation part 300, the photographing part 400, the distance sensor 500, and the driving part 700 so that the lower substrate W1 and the upper substrate W2 are aligned. For example, the controller 600 may calculate an alignment error value or misalignment degree of the lower substrate W1 and the upper substrate W2 based on an alignment image of the lower substrate W1 and the upper substrate W2 measured from the photographing part 400 and correct the alignment error or misalignment by driving the driving part 700. For another example, the controller 600 may control vacuum pressure provided to the lower vacuum hole 120 so that the first chuck 100 fixes the lower substrate W1 on the first chuck 100 or separates the lower substrate W1 from the first chuck 100. The controller 600 may control vacuum pressure provided to the upper vacuum hole 220 so that the second chuck 200 fixes the upper substrate W2 on the second chuck 200 or separates the upper substrate W2 from the second chuck 200. For yet another example, the controller 600 may control a drive of the vertical supporter 130. For example, when the distance between the lower substrate W1 and the upper substrate W2 measured by the distance sensor 500 is at a reference value, the vertical supporter 130 may be lifted in the first direction D1 by the controller 600.

According to some example embodiments, the controller 600 may be implemented in hardware, firmware, software, or any combination thereof. For example, the controller 600 may include or may be a computing device such as a workstation computer, a desktop computer, a laptop computer, a tablet computer, or the like. In certain embodiments, the controller 600 may include or may be a simple controller, a complex processor such as a microprocessor, a central processing unit (CPU), and a graphic processing unit (GPU), a processor configured by software, or dedicated hardware or firmware. The controller 600 may be implemented by, for example, a general-use computer or application specific hardware such as digital signal process (DSP), field programmable gate array (FPGA), and application-specific integrated circuit (ASIC). The controller 600 may be implemented by instructions stored in a machine-readable medium which may be read and executed by one or more processors. Here, the machine-readable medium may include or may be any mechanism for storing and/or transmitting information in a machine (for example, computing device) readable form. For example, the machine-readable medium may include or may be read-only memory (ROM), random access memory (RAM), a magnetic disk storage medium, an optical storage medium, flash memory devices, electric, optical, acoustic, or other forms of radio signals (for example, carrier wave, infrared signal, and digital signal) and any other signals.

According to some example embodiments, the driving part 700 may be connected to the first chuck 100. The driving part 700 may control a movement of the first chuck 100. The driving part 700 may control a vertical movement (a movement in the first direction D1) of the first chuck 100, a horizontal movement (a movement in the second direction D2 and the third direction D3), and a rotational movement. For example, the first chuck 100 may move in the first direction D1 by the driving part 700. Although it is illustrated that the driving part 700 is connected to the first chuck 100 alone, the inventive concept is not limited thereto. For example, the driving part 700 may also be connected to the second chuck 200, the photographing part 400, and the actuator 305 in certain embodiments.

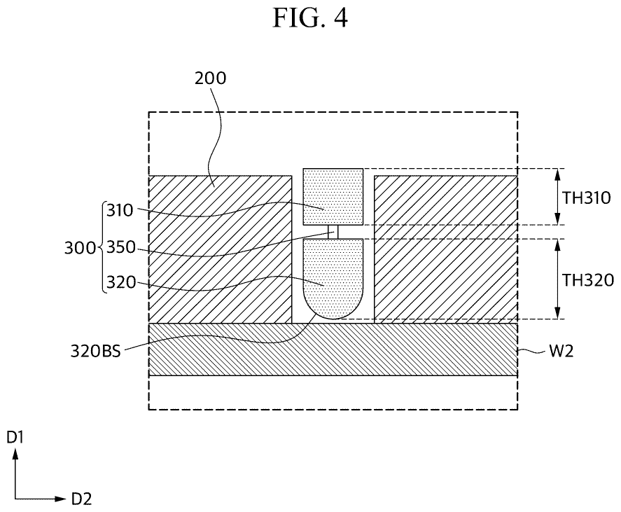

FIGS. 4 to 8 are examples of enlarged views showing part P of FIG. 2 according to some other example embodiments. For convenience of description, differences from the descriptions with reference to FIGS. 1 to 3 are mainly described.

Referring to FIG. 4, the thickness TH310 of the first pressurizing part and the thickness TH320 of the second pressurizing part may be different from each other. For example, the thickness TH320 of the second pressurizing part may be greater than the thickness TH310 of the first pressurizing part. For example, a distance between the upper surface and the lowermost point of the second pressurizing part 320 may be greater than a distance between the upper surface and the bottom surface of the first pressurizing part 310. The second pressurizing part 320 with a greater thickness than the first pressurizing part 310 may effectively absorb vibration or impact generated due to a strike/push of the first pressurizing part 310.

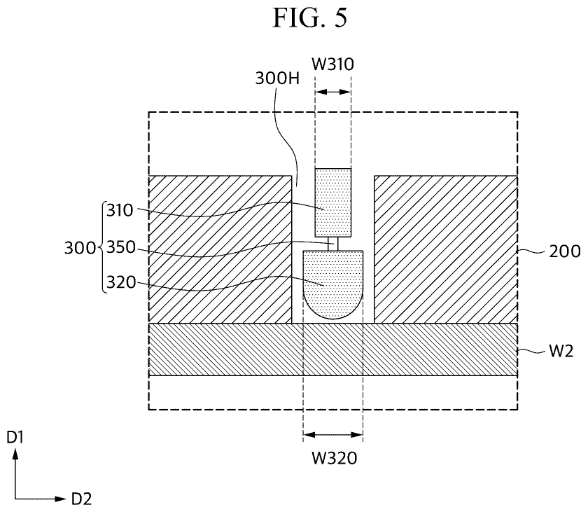

Referring to FIG. 5, a width/diameter W320 of the second pressurizing part may be greater than a width/diameter W310 of the first pressurizing part. For example, the upper surface of the second pressurizing part 320 facing the first pressurizing part 310 may have a greater area than the bottom surface of the first pressurizing part 310. Therefore, the second pressurizing part 320 may effectively absorb vibration or impact generated due to pressurization/thrust of the first pressurizing part 310.

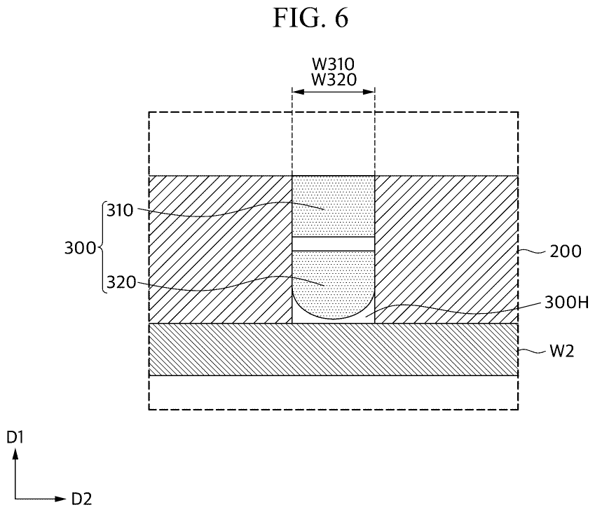

Referring to FIG. 6, the width W310 of the first pressurizing part and the width W320 of the second pressurizing part may be identical to the width 300H of the through hole. For example, the first pressurizing part 310 and the second pressurizing part 320 may be in contact with the second chuck 200 within the through hole 300H. For example, side surfaces of the first pressuring part 310 and the second pressuring part 320 may contact a sidewall of the through hole 300H. For example, each of the width W310 of the first pressurizing part and the width W320 of the second pressurizing part may correspond to or substantially the same as the width 300H of the through hole. The first pressurizing part 310 and the second pressurizing part 320 may not be connected to each other through the connection part (350 of FIG. 3) but be separated and spaced apart from each other. When the first pressurizing part 310 and the second pressurizing part 320 sequentially move in the first direction D1 and pressurize the upper substrate W2, the first pressurizing part 310 and the second pressurizing part 320 may move in the first direction D1 while being in contact with and rubbing/sliding on the second chuck 200 (on the sidewall of the through hole 300H). Accordingly, before the first pressurizing part 310 strikes/pushes the second pressurizing part 320, a magnitude of vibration may be partially decreased due to friction to the second chuck 200. Similarly, following the strike/push of the first pressurizing part 310, the second pressurizing part 320 may rub/slide on the second chuck 200 before striking the upper substrate W2 and a magnitude of vibration may be partially decreased. However, even in this case, the second pressurizing part 320 may strike/push the upper substrate W2 with enough strength for the upper substrate W2 to be separated from the second chuck 200.

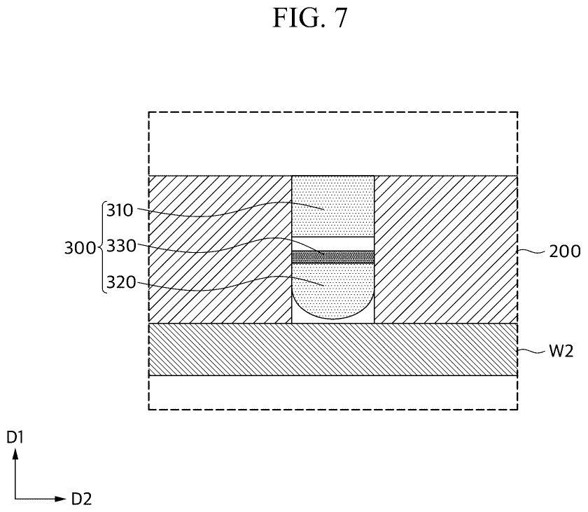

Referring to FIG. 7, the bonding initiation part 300 may further include an impact absorption part 330. The impact absorption part 330 may be disposed between the first pressurizing part 310 and the second pressurizing part 320. The impact absorption part 330 may be disposed on the upper surface of the second pressurizing part 320 facing the first pressurizing part 310. The impact absorption part 330 may include, for example, a material with greater elasticity than the first pressurizing part 310 and the second pressurizing part 320. The impact absorption part 330 may partially absorb vibration or impact generated when the first pressurizing part 310 strikes/pushes the second pressurizing part 320. For example, the impact absorption part 330 may be an elastic pad partially absorbing vibration/impact or a deformable pad partially absorbing vibration/impact by deforming its shape. Accordingly, a magnitude of vibration or impact transmitted to the upper substrate W2 when the second pressurizing part 320 strikes the upper substrate W2 may decrease.

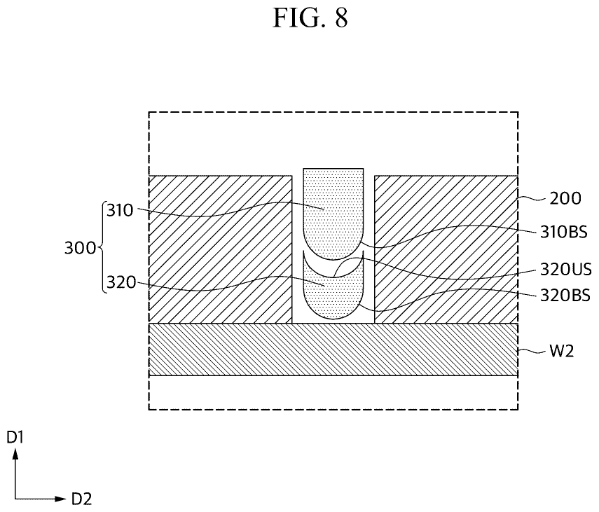

Referring to FIG. 8, a bottom surface 310BS of the first pressurizing part 310 may be formed as a curved surface convex toward an upper surface 320US of the second pressurizing part 320. The bottom surface 310BS of the first pressurizing part 310 may be formed along a profile of the upper surface 320US of the second pressurizing part 320. For example, the bottom surface 310BS of the first pressurizing part 310 may include a curved surface with an identical curvature to the upper surface 320US of the second pressurizing part 320. For example, the bottom surface 310BS of the first pressurizing part 310 may be a convex surface and the upper surface 320US of the second pressurizing part 320 may be a concave surface.

According to some example embodiments, the upper surface 320US of the second pressurizing part 320 may be formed as a concave surface. The upper surface 320US of the second pressurizing part 320 may have a shape corresponding to the bottom surface 310BS of the first pressurizing part 310. The upper surface 320US of the second pressurizing part which is formed as the curved surface may have an increased surface area compared to a planar shape. Therefore, the second pressurizing part 320 may effectively mitigate vibration and/or impact generated when the first pressurizing part 310 strikes/pushes the second pressurizing part 320, which may mitigate vibration and/or impact transmitted to the upper substrate W2 when the second pressurizing part 320 strikes/pushes the upper substrate W2. In certain embodiments, the bottom surface 310BS of the first pressurizing part 310 may be a concave surface and the upper surface 320US of the second pressurizing part 320 may be a convex surface differently from the embodiment illustrated in FIG. 8. In this case, the mitigating effect of vibration/impact may be similar to the embodiment illustrated in FIG. 8.

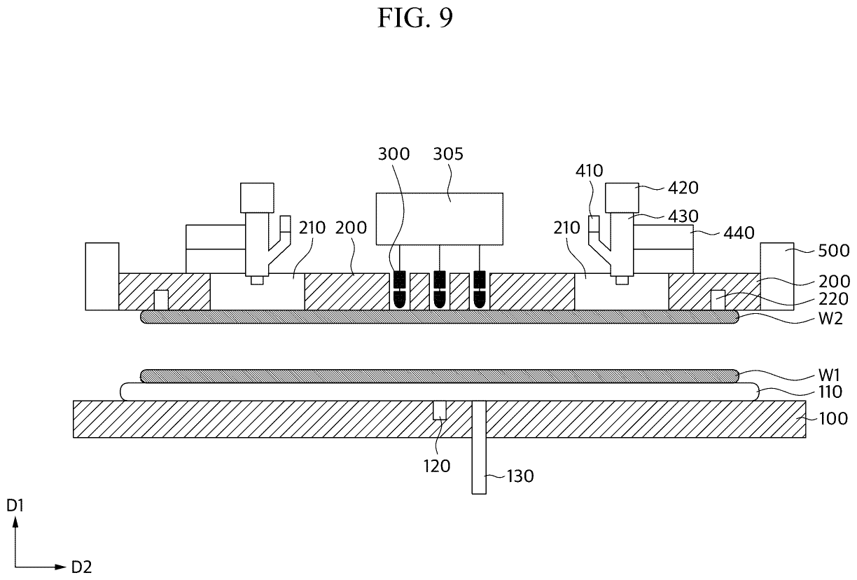

FIG. 9 is a cross-sectional view for illustrating a substrate bonding device according to still other example embodiments. For convenience of description, differences from the descriptions with reference to FIGS. 1 to 3 are mainly described.

Referring to FIG. 9, the substrate bonding device may include a plurality of bonding initiation parts (e.g., presses) 300. The plurality of bonding initiation parts 300 may be disposed at the center portion of the second chuck 200. For example, upper vacuum holes 220 may be disposed at outer portions of the second chuck 200 compared to the bonding initiation part 300. For example, a plurality of upper vacuum holes 220 may be formed along a circumference of the second chuck 200. The plurality of bonding initiation parts 300 may be disposed at the center portion of the second chuck 200 between the upper vacuum holes 220.

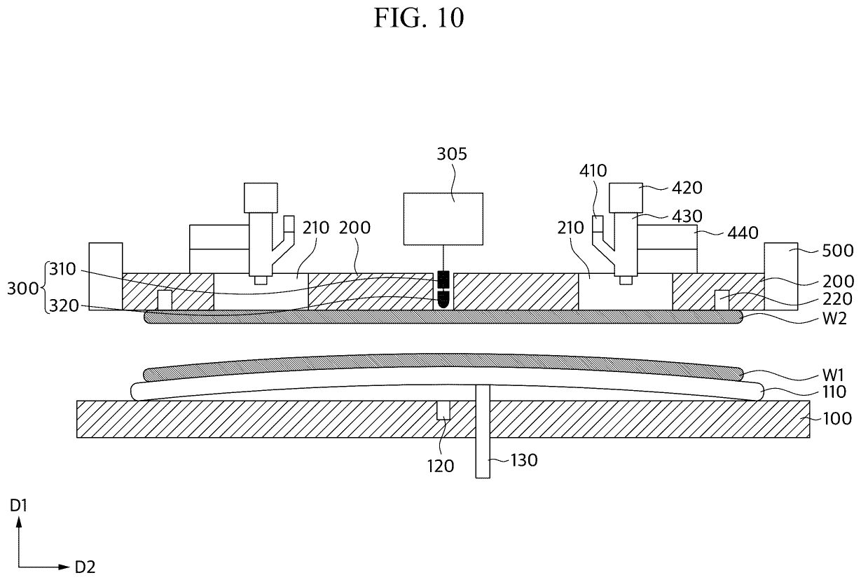

FIGS. 10 to 13 are diagrams for illustrating a method of bonding substrates according to some example embodiments.

Referring to FIG. 10, a method of bonding substrates according to some example embodiments may include disposing a lower substrate W1 on the first chuck 100 and disposing an upper substrate W2 on the second chuck 200. For example, disposing the lower substrate W1 on the first chuck 100 may include disposing the lower substrate W1 on the support plate 110 on the first chuck 100.

According to some example embodiments, as the support plate 110 lifts in the first direction D1, the lower substrate W1 may be closer to the upper substrate W2. The vertical supporter 130 may lift the support plate 110 toward the second chuck 200. For example, the vertical supporter 130 may move the center portion of the support plate 110 upwards in the first direction D1. In this case, vacuum pressure may not be provided from the lower vacuum hole 120. Accordingly, the support plate 110 may be separated from the first chuck 100. The edge portion of the support plate 110 may not move in the first direction D1 and be disposed on the first chuck 100.

According to some example embodiments, as the center portion of the support plate 110 is lifted in the first direction D1 by the vertical supporter 130 and the edge portion of the support plate 110 is disposed on the first chuck 100, the support plate 110 may have a bent shape. The lower substrate W1 disposed on the support plate 110 may also have a bent shape along with the shape of the support plate 110. The center portion of the lower substrate W1 may be closer to the upper substrate W2.

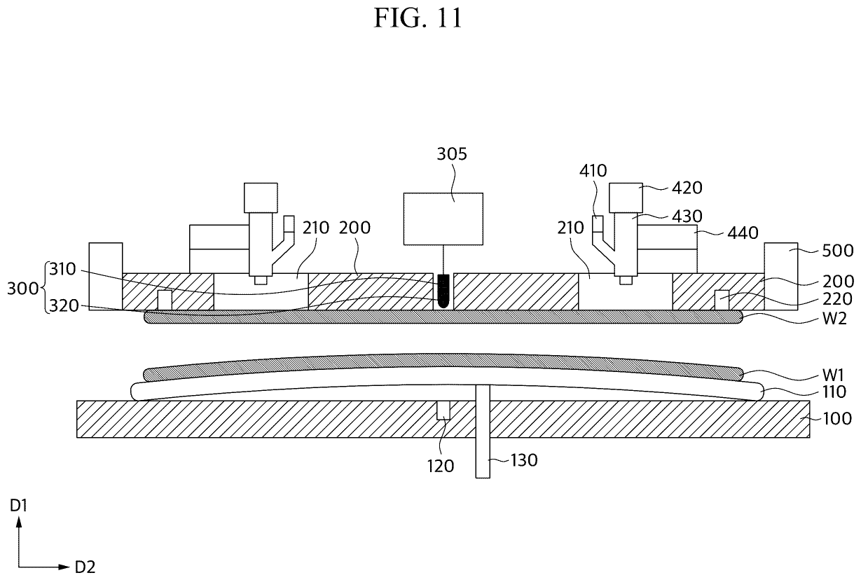

Then, referring to FIG. 11, the method of bonding the substrate according to some example embodiments may include striking/pushing the second pressurizing part 320 by moving the first pressurizing part 310 downwards in the first direction D1. The first pressurizing part 310 may move in the first direction D1 and be in contact with the upper surface of the second pressurizing part 320.

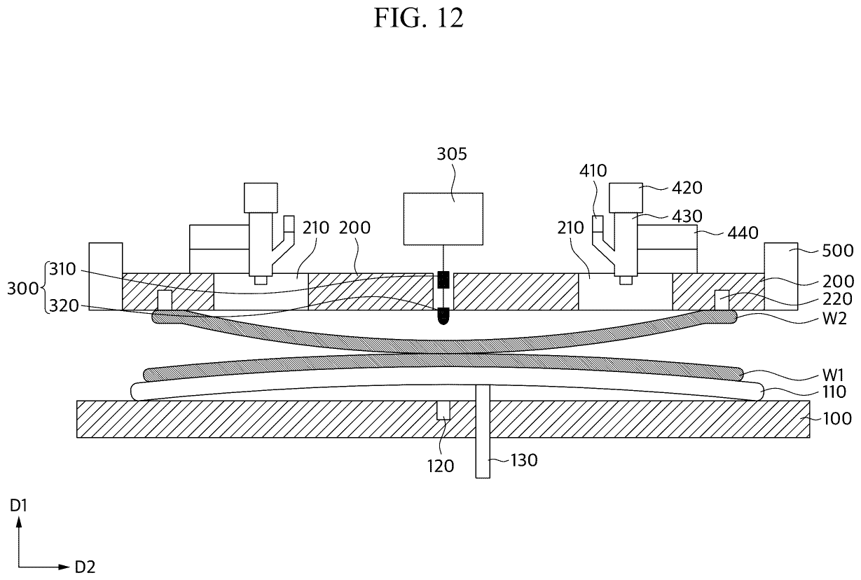

Then, referring to FIG. 12, the method of bonding the substrate according to some example embodiments may include striking/pushing the upper substrate W2 by moving the second pressurizing part 320 downwards in the first direction D1.

According to some example embodiments, the second pressurizing part 320 struck/pushed by the first pressurizing part 310 may sequentially strike/push and pressurize the upper substrate W2 downwards. As the second pressurizing part 320 strikes/pushes the upper substrate W2, a center portion of the upper substrate W2 may be separated from the second chuck 200. In this case, vacuum pressure may be provided from the upper vacuum holes 220, and edge portions of the upper substrate W2 may adhere to the second chuck 200. Therefore, the center portion alone of the upper substrate W2 struck by the second pressurizing part 320 may be separated from the second chuck 200, which may make a bent shape with the center portion bulging toward the lower substrate W1. Bonding may be initiated from the center portion of the lower substrate W1 and the center portion of the upper substrate W2.

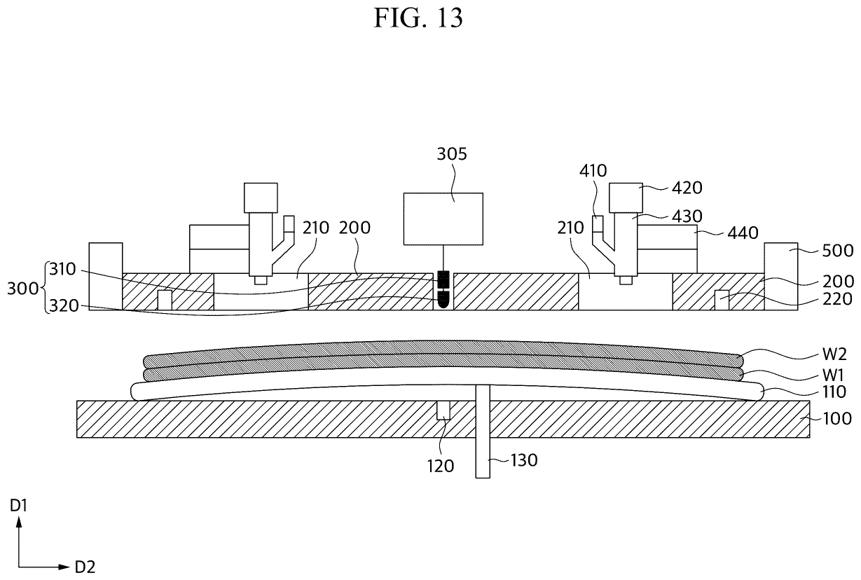

Then, referring to FIG. 13, the upper substrate W2 may be separated from the second chuck 200 and completely bonded with the lower substrate W1.

According to some example embodiments, vacuum pressure may not be provided from the upper vacuum hole 220 and the edge portion of the upper substrate W2 may also be separated from the second chuck 200, e.g., after the center portion of the upper substrate W2 from the second chuck 200 or when the second pressurizing part 320 strikes/pushes the upper substrate W2.

While various example embodiments of the present disclosure are described in detail above, the inventive concept is not limited thereto, and it will be apparent to those of ordinary skill in the art that modifications and variations may be made without departing from the scope of the present disclosure as defined by the appended claims. In addition, the aforementioned example embodiments may be implemented with some elements removed, and each example embodiment may be implemented in combination with each other. For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

What is claimed is:

1. A substrate bonding device comprising:
a first chuck configured to support a lower substrate;
a second chuck configured to grip an upper substrate facing the lower substrate in a first direction perpendicular to an upper surface of the lower substrate; and
a press disposed at a center of the second chuck and configured to push the upper substrate toward the lower substrate in the first direction,
wherein the press includes a first pressurizing part and a second pressurizing part which are spaced apart from each other in the first direction.

2. The substrate bonding device of claim 1, wherein the second pressurizing part is closer to the upper substrate than the first pressurizing part, and
wherein a bottom surface of the second pressurizing part is a curved surface convex toward the upper substrate.

3. The substrate bonding device of claim 1, wherein the second pressurizing part is closer to the upper substrate than the first pressurizing part, and
wherein an upper surface of the second pressurizing part is a concave surface and a bottom surface of the first pressurizing part is a curved surface convex toward the upper surface of the second pressurizing part.

4. The substrate bonding device of claim 1, wherein the press further includes an elastic connector connecting the first pressurizing part and the second pressurizing part to each other, and
wherein the elastic connector is formed with an elastic material.

5. The substrate bonding device of claim 1, wherein the first pressurizing part and the second pressurizing part include an elastic material.

6. The substrate bonding device of claim 1, wherein the second chuck includes a through hole in which the press is disposed, and
wherein a width of the press is less than a width of the through hole.

7. The substrate bonding device of claim 1, wherein the second chuck includes a through hole in which the press is disposed,
wherein the second pressurizing part is closer to the upper substrate than the first pressurizing part, and
wherein a width of the second pressurizing part corresponds to a width of the through hole.

8. The substrate bonding device of claim 1, wherein a width of the first pressurizing part and a width of the second pressurizing part are different from each other.

9. The substrate bonding device of claim 1, wherein, in the first direction, a sum of a thickness of the first pressurizing part and a thickness of the second pressurizing part is equal to or less than a thickness of the second chuck.

10. The substrate bonding device of claim 1, wherein, in the first direction, a thickness of the second pressurizing part is greater than a thickness of the first pressurizing part.

11. The substrate bonding device of claim 1, wherein the second chuck includes a vacuum hole disposed at an outer portion of the second chuck compared to the press and configured to grip the upper substrate.

12. The substrate bonding device of claim 1, wherein the substrate bonding device comprises a plurality of presses.

13. The substrate bonding device of claim 1, wherein the press includes an elastic pad disposed on a surface of the second pressurizing part facing the first pressurizing part.

14. A substrate bonding device comprising:
a first chuck configured to support a lower substrate;
a second chuck configured to support an upper substrate facing the lower substrate in a first direction perpendicular to an upper surface of the lower substrate; and
a press disposed in a hole penetrating through a center of the second chuck and configured to push the upper substrate toward the lower substrate in the first direction,
wherein the press includes a first pressurizing part and a second pressurizing part which are spaced apart from each other in the first direction,
wherein the first pressurizing part is configured to contact an upper surface of the second pressurizing part when moved along the first direction, and
wherein the second pressurizing part is configured to contact the upper substrate when moved along the first direction.

15. The substrate bonding device of claim 14, wherein each of the first pressurizing part and the second pressurizing part include an elastic material.

16. The substrate bonding device of claim 14, wherein, in the first direction, a thickness of the first pressurizing part and a thickness of the second pressurizing part are different from each other.

17. The substrate bonding device of claim 14, further comprising a vertical supporter configured to penetrate through the first chuck and move the lower substrate toward the upper substrate.

18. The substrate bonding device of claim 14, wherein a bottom surface of the second pressurizing part is a curved surface convex toward the upper substrate.

19. A method of bonding substrates, the method comprising:
providing a substrate bonding device including a first chuck, a second chuck facing the first chuck in a first direction perpendicular to an upper surface of the first chuck, and a press disposed in a hole penetrating through a center of the second chuck and including a first pressurizing part and a second pressurizing part which are aligned in the first direction;
disposing a lower substrate on the first chuck;
disposing an upper substrate on the second chuck;
striking the second pressurizing part by moving the first pressurizing part in the first direction;
striking a center portion of the upper substrate by moving the second pressurizing part in the first direction; and
bonding the center portion of the upper substrate to the lower substrate by separating the center portion of the upper substrate from the second chuck.

20. The method of claim 19, wherein the bonding the center portion of the upper substrate to the lower substrate by separating the center portion of the upper substrate from the second chuck includes attaching an edge portion of the upper substrate to the second chuck by providing vacuum pressure to the edge portion of the upper substrate through a vacuum hole disposed at an outer portion of the second chuck compared to the press.
